(19) United States
(12) Patent Application Publication
(10) Pub. No.: US 2005/0133298 A1
(43) Pub. Date: Jun. 23, 2005

(54) Speaker box for use in back-load horn

(76) Inventor: Yasuei Hasegawa, Sanjo-shi (JP)

Correspondence Address: WENDEROTH, LIND & PONACK, L.L.P., 2033 K STREET N. W., SUITE 800, WASHINGTON, DC, 20006-1021, US

(21) Appl. No.: 10/740,809

(22) Filed: Dec. 22, 2003

(51) Int. Cl. A47B 81/06; H05K 5/00

(52) U.S. Cl. 181/199; 181/148

(57) ABSTRACT

A speaker box that is furnished inside a main body thereof with a curved sound channel, and used in a back-load horn, adopts a structure comprising two lateral plates and a plurality of intermediate plates interposed between the lateral plates, which plates are joined in a laminated form and secured with bolts. The intermediate plates individually have curved walls that jointly define a sound channel inside the main body of the speaker box.

### BACKGROUND OF THE INVENTION

1. Field of the Invention

This invention relates to a speaker box for use in a back-load horn furnished in an interior of a main body thereof with a curved sound channel.

2. Description of Related Art

Among enthusiasts for audio, a back-load horn system has been attracting great attention because the system, even though used in a small speaker unit, is characterized by enabling depth of body of a low tone zone of sound to be exalted by allowing high sound and intermediate sound emanating from a front surface of the speaker unit to be directly radiated and causing the low sound emanating backward from the system to be passed through a long sound channel and reproduced orthodoxly.

Various attempts directed toward development of a speaker box for use in the back-load horn system of this principle have been underway. Since the speaker box is required to form therein a long sound channel curved intricately with an object of amplifying low sound, formation of this sound channel imposes various restrictions on tasks of design and manufacture.

Today, a box-shaped main body is obtained by cutting a wood plate material, such as lauan plywood or linden plywood, into pieces of necessary dimensions and assembling properly cut pieces with nails and adhesive agents, and meanwhile a sound channel for amplifying low sound is formed inside the box-shaped main body, and a product consequently obtained is used as a speaker box for a back-load horn as described in the magazine “Stereo, July 2000 issue” published by Ongakunotomo-Sha K. K.

A conventional speaker box of this construction, however, has proved unsuitable for mass production because it has required work of cutting numerous wood plate materials into pieces of necessary dimensions, and manually assembling these cut pieces with strict accuracy and automatically rendered tasks of design and manufacture very irksome. Notwithstanding that the sound channel for the back-load horn is inherently required to ideally be of an intricately curved long curvilinear shape, it is virtually impossible to form an intricately curved sound channel by merely assembling rectangular plate materials. Thus, a strong point of the back-load horn cannot be fully satisfactorily utilized. Moreover, it is not easy for the sound channel to acquire a closed structure, no matter how heedfully the cut pieces of plate materials may be assembled. In consequence of this difficulty, a produced speaker box has a possibility of inducing leakage of sound.

### SUMMARY OF THE INVENTION

This invention, which has been developed with a view to effectively solving such problems as have been encountered by the conventional speaker box for a back-load horn, concerns a speaker box furnished inside a main body thereof with a sound channel and used in a back-load horn. The speaker box comprises two lateral plates and a plurality of intermediate plates interposed between the lateral plates, which are joined in a laminated form and secured with bolts. The intermediate plates individually have curved walls that jointly define a sound channel inside the main body thereof.

In this invention, therefore, a speaker box furnished inside the main body thereof with a highly accurately curved sound channel can be obtained simply by performing an economically inexpensive NC (numerical control) machining on a plurality of intermediate plates interposed between two lateral plates, thereby forming therein curved walls jointly defining a sound channel, and subsequently joining the intermediate plates and the two lateral plates in a laminated form and securing them with bolts. Thus, anyone can manufacture this speaker box with ease. Particularly, the structure mentioned above can promise provision of highly mass-producible and inexpensive speaker boxes.

Securement with bolts provides a perfect solution to a problem of sound leakage because this prevents individual curved walls from including unnecessary gaps therebetween. Variation of sound can also be enjoyed by properly deciding a number of intermediate plates. Furthermore, turbulence of sound reflection and air current can be allayed, and turbidity of sound can be eliminated because corner parts in the sound channel may be finished in curvilinear shapes, and diverging parts in the sound channel may be finished in curvilinear shapes, designed in advance by calculation.

### BRIEF DESCRIPTION OF THE DRAWINGS

FIG. 1 is an exploded perspective view of a speaker box for use in a back-load horn according to one embodiment of this invention.

FIG. 2 is a side view of a single intermediate plate.

FIG. 3 is a perspective view illustrating a main body of the speaker box in an assembled state.

FIG. 4 is a perspective view illustrating a state in which an attachment hole for fixing a speaker unit is formed in the main body of an assembled speaker box.

### DESCRIPTION OF THE PREFERRED EMBODIMENT

Now, this invention will be described in detail below with reference to a preferred embodiment thereof illustrated in the drawings. A speaker box for use in a back-load horn according to the embodiment is unexceptionally formed by assembling wood plate materials, such as wood fiberboards (MDF boards=medium-density fiber boards). The speaker box differs from a conventional speaker box in that a main body of the speaker box is finished in a laminated form.

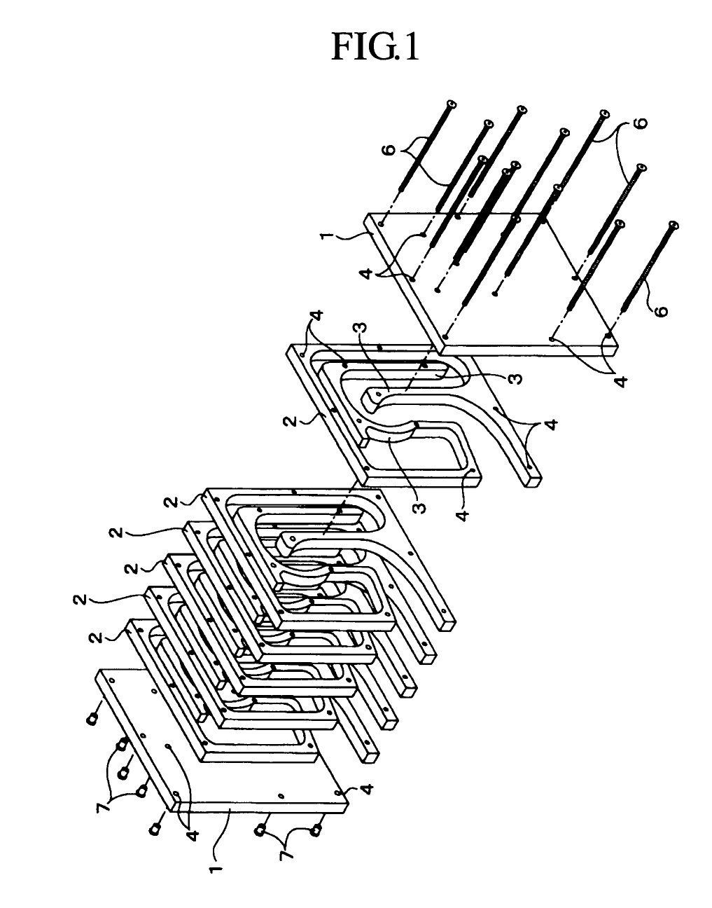

To be more specific, the speaker box according to the embodiment of this invention comprises two lateral plates 1, destined to form lateral walls of the main body of the speaker box, and a plurality of intermediate plates 2 interposed between the two lateral plates 1 as illustrated in FIG. 1. The speaker box is characterized by forming equal curved walls 3 destined to define jointly a sound channel coincidently in the intermediate plates 2, and joining these intermediate plates 2 and the two lateral plates 1 in a laminated form and securing them with bolts 6. Thus, the lateral plates 1 and the intermediate plates 2 individually are perforated uniformly in advance to form therein insertion holes 4 for allowing insertion of the bolts 6 therethrough, together with curved walls 3.

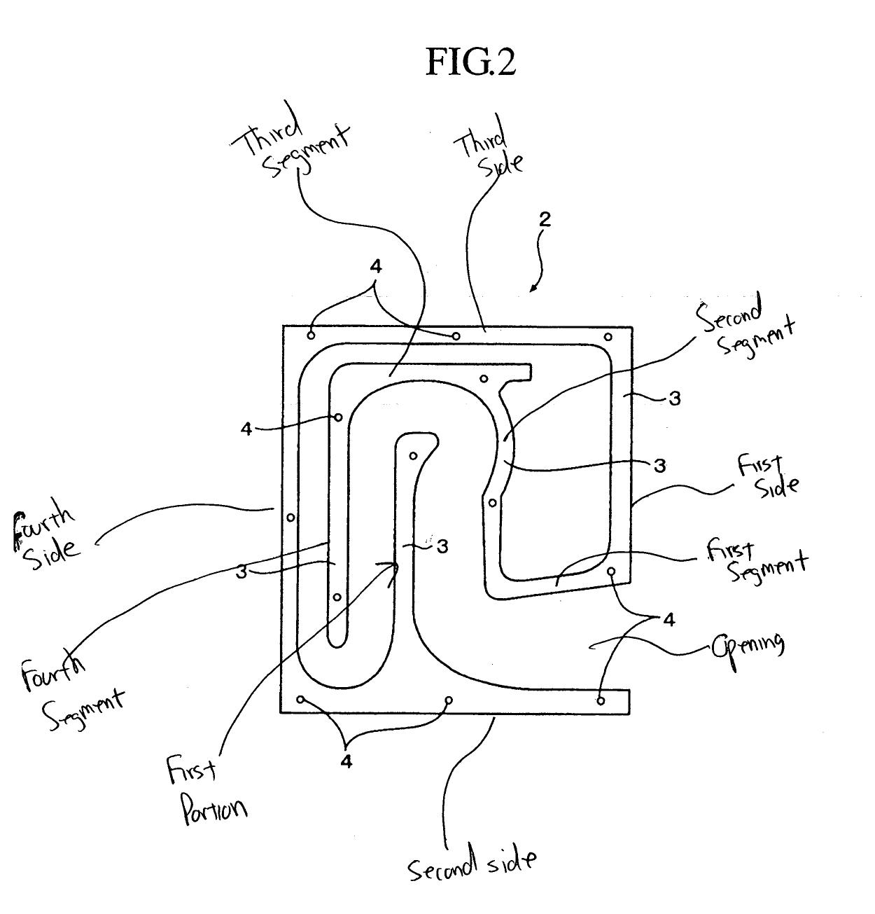

As regards the curved walls 3, since they are expected to be formed by economically inexpensive NC machining in a perforated form, they can be finished in a curved shape of whatever sort designed in advance. In this case, it is proper to devise a way of allaying turbulence of sound reflection and air current, and eliminating turbidity of sound, by at least imparting curvilinear shapes to corner parts in a sound channel and imparting curvilinear shapes as well to diverging parts in the sound channel as illustrated in FIG. 2.

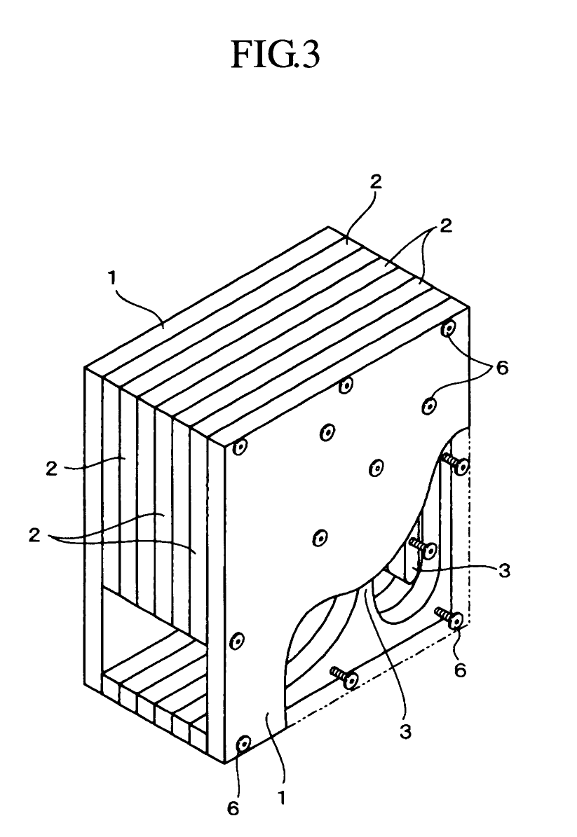

In assembling a speaker box according to the embodiment of this invention, therefore, an arbitrarily selected number of intermediate plates 2 are interposed between two lateral plates 1, bolts 6 are inserted through the insertion holes 4, and distal end parts of the bolts 6 are individually tightened with nuts 7. Consequently, the speaker box is easily completed faithfully in the shape of a box and, at the same time, the sound channel, ideally curved with the curved walls 3 formed individually in the intermediate plates 2, is completed inside the main body of the speaker box as illustrated in FIG. 3.

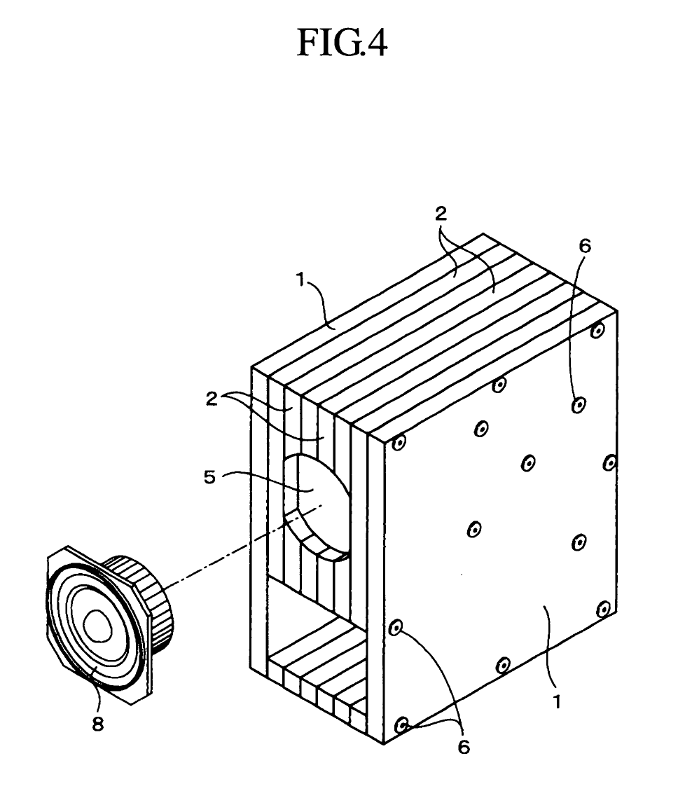

For the purpose of attaching a speaker unit 8 to the main body of this assembled speaker box, a fitting hole 5 is formed by boring with a cutter on a front surface side of the laminated intermediate plates 2, as illustrated in FIG. 4, and the speaker unit 8 is fitted in the fitting hole 5. In this case, work of boring the fitting hole 5 as with a cutter may be performed easily by having a separation groove, intended to facilitate the boring, formed in advance at a relevant site, though not specifically shown in the drawings. Optionally, a plurality of such separation grooves may be formed and such a number of these separation grooves, as is commensurate with the size of the speaker unit 8, may be utilized for necessary separation. This is just one of examples of a method of effecting attachment under discussion. Other methods are available for attachment of the speaker unit 8 to the main body of the speaker box.

In the speaker box for use in the back-load horn according to the present embodiment of the invention, therefore, the sound channel aimed at can be formed with accuracy in the main body of the speaker box by simply subjecting the intermediate plates 2 to NC machining, thereby forming therein such equal curved walls 3 as jointly define the sound channel. Consequently, a speaker box which allows very easy manufacture, abounds in mass-productivity, and proves inexpensive as compared with the conventional speaker box, can be provided.

The work of joining the intermediate plates 2 and the lateral plates 1 in a laminated form and securing them together with the bolts 6 obviates necessity for such work as nailing, using an adhesive agent, and chiseling. It goes without saying that even this fact alone serves a purpose of facilitating manufacture of the speaker box. Since the intermediate plates 2 are moreover secured strongly, a possibility of the curved walls 3 entailing a problem of including gaps mutually therebetween and arousing anxiety about sound leakage are eliminated. The curved walls 3, when necessary, may be mutually joined via an adhesive agent. This option does not need to be denied.

Further, the NC machining results in allaying turbulence of sound reflection and air current, and eliminating turbidity of sound, because such machining is capable of finishing the corner parts in the curved sound channel and the diverging parts in the sound channel both in curvilinear shapes.

In the laminated structure, variation of sound can be enjoyed because a number of intermediate plates 2 may be arbitrarily fluctuated. As regards the intermediate plates 2 which are to be joined in a laminated form, resonance of the main body of the speaker box can be allayed by preparing plate materials having different modes of resonance and piling them alternately.

As described above, this invention, owing to adoption of the structure of the foregoing description, is enabled to obtain a speaker box furnished inside the main body thereof with a curved sound channel of high accuracy by simply subjecting a plurality of intermediate plates interposed between two lateral plates to economically inexpensive NC machining, thereby forming equally curved walls destined to define jointly a sound channel and thereafter stacking these intermediate plates and the two lateral walls in a laminated form and securing them with bolts. It goes without saying that anybody can easily manufacture this speaker box. Particularly, in the structure described above, the speaker box which abounds in mass-productivity and proves inexpensive can be provided.

Then, securing with bolts, which is incapable of causing the curved walls to include unnecessary gaps therebetween, provides a perfect solution to a problem of sound leakage. A proper decision of the number of intermediate plates promises enjoyment of variations of sound. Furthermore, that the corner parts in the sound channel can be finished in curvilinear shapes, and the diverging parts in the sound channel can be finished likewise in curvilinear shapes, conforming to design drawn in advance based on calculation, brings an effect of allaying turbulence of sound reflection and air current, and eliminating turbidity of sound.

1. (canceled)

2. A speaker box comprising:
intermediate plates positioned between and interconnected with two lateral plates so as to define a unitary body,
wherein each of said intermediate plates has a curved wall defining an opening in a peripheral surface of said each of said intermediate plates, and cooperates with the curved wall of an immediately adjacent one of said intermediate plates, so as to define a sound channel in said unitary body.

3. The speaker box according to claim 2, wherein
said intermediate plates and said two lateral plates are interconnected via bolts.

4. The speaker box according to claim 3, wherein
said curved wall of said each of said intermediate plates is identical to said curved wall of said immediately adjacent one of said intermediate plates.

5. The speaker box according to claim 4, wherein
each of said intermediate plates has four sides, with said opening being in one of said four sides, and
said curved wall of each of said intermediate plates includes
(i) a first portion extending from a second of said four sides toward a third of said four sides, and
(ii) a second portion extending from said one of said four sides and around said first portion.

6. The speaker box according to claim 5, wherein
said second portion includes
(i) a first segment directed toward said first portion and defining a boundary of said opening,
(ii) a second segment extending from said first segment toward said third of said four sides and positioned between said first portion and said one of said four sides,
(iii) a third segment extending from said second segment toward a fourth of said four sides and positioned between said first portion and said third of said four sides, and
(iv) a fourth segment extending from said third segment toward said second of said four sides and positioned between said first portion and said fourth of said four sides.

7. The speaker box according to claim 3, wherein
each of said intermediate plates has four sides, with said opening being in one of said four sides, and
said curved wall of each of said intermediate plates includes
(i) a first portion extending from a second of said four sides toward a third of said four sides, and
(ii) a second portion extending from said one of said four sides and around said first portion.

8. The speaker box according to claim 7, wherein
said second portion includes
(i) a first segment directed toward said first portion and defining a boundary of said opening,
(ii) a second segment extending from said first segment toward said third of said four sides and positioned between said first portion and said one of said four sides,
(iii) a third segment extending from said second segment toward a fourth of said four sides and positioned between said first portion and said third of said four sides, and
(iv) a fourth segment extending from said third segment toward said second of said four sides and positioned between said first portion and said fourth of said four sides.

9. The speaker box according to claim 2, wherein
said curved wall of said each of said intermediate plates is identical to said curved wall of said immediately adjacent one of said intermediate plates.

10. The speaker box according to claim 9, wherein
each of said intermediate plates has four sides, with said opening being in one of said four sides, and
said curved wall of each of said intermediate plates includes
(i) a first portion extending from a second of said four sides toward a third of said four sides, and
(ii) a second portion extending from said one of said four sides and around said first portion.

11. The speaker box according to claim 10, wherein
said second portion includes
(i) a first segment directed toward said first portion and defining a boundary of said opening,
(ii) a second segment extending from said first segment toward said third of said four sides and positioned between said first portion and said one of said four sides,
(iii) a third segment extending from said second segment toward a fourth of said four sides and positioned between said first portion and said third of said four sides, and
(iv) a fourth segment extending from said third segment toward said second of said four sides and positioned between said first portion and said fourth of said four sides.

12. The speaker box according to claim 2, wherein
each of said intermediate plates has four sides, with said opening being in one of said four sides, and
said curved wall of each of said intermediate plates includes
(i) a first portion extending from a second of said four sides toward a third of said four sides, and
(ii) a second portion extending from said one of said four sides and around said first portion.

13. The speaker box according to claim 12, wherein
said second portion includes
(i) a first segment directed toward said first portion and defining a boundary of said opening,
(ii) a second segment extending from said first segment toward said third of said four sides and positioned between said first portion and said one of said four sides,
(iii) a third segment extending from said second segment toward a fourth of said four sides and positioned between said first portion and said third of said four sides, and
(iv) a fourth segment extending from said third segment toward said second of said four sides and positioned between said first portion and said fourth of said four sides.
